(19) United States
(12) Patent Application Publication
(10) Pub. No.: US 2026/0314124 A1
(43) Pub. Date: Oct. 8, 2026

(54) LIGHT EMITTING MODULE

(71) Applicant: SEOUL VIOSYS CO., LTD., Ansan-si (KR)

(72) Inventor: Sungki HWANG, Ansan-si (KR)

(73) Assignee: SEOUL VIOSYS CO., LTD., Ansan-si (KR)

(21) Appl. No.: 19/637,193

(22) Filed: Apr. 2, 2026

Related U.S. Application Data
(60) Provisional application No. 63/783,390, filed on Apr. 4, 2025.

(51) Int. Cl. H10H 20/84; H10H 20/855

(52) U.S. Cl. CPC H10H 20/84; H10H 20/855

(57) ABSTRACT

The present invention discloses a light emitting apparatus installed on a side wall of a structure having an angled corner, in which an illuminance measured along a reference line that is perpendicular to a bisecting line that evenly divides a corner angle formed at the corner and is spaced apart by a predetermined distance in an extension direction of the bisecting line has a maximum value at a central position corresponding to the bisecting line.

### CROSS-REFERENCE TO RELATED APPLICATIONS

This application is based upon and claims the benefit of US Provisional Patent Application No. 63/783,390 filed Apr. 4, 2025, the entire contents of which are incorporated herein by reference.

### TECHNICAL FIELD

The present invention relates to a light emitting apparatus including a light emitting device.

### BACKGROUND ART

A light emitting diode (LED) is one of light emitting devices that emit light when a current is applied thereto. Recently, the light emitting diodes have been widely used in various technical fields such as display apparatuses, vehicle lamps, and general lighting. Moreover, the light emitting diode offers advantages such as a long lifespan, low power consumption, and fast response speed. Taking full advantage of these benefits, they are rapidly replacing a conventional light source. For example, a display apparatus using the light emitting diode may be fabricated by forming structures of individually grown red R, green G, and blue B light emitting diodes (LEDs) on a final substrate.

A light emitting apparatus including the light emitting diode can be configured as a display installed in various locations such as an exterior wall of a building, indoor columns, and indoor side walls, or others. Such a display can provide information. However, structures such as building exterior walls, indoor columns, and side walls typically include corners where two walls meet at an angle. When the light-emitting apparatus is installed at a corner, it is necessary to achieve uniform and bright luminance without creating any dark regions.

### DISCLOSURE

### Technical Problem

The present invention may provide a light emitting apparatus capable of achieving uniform and bright luminance without any dark regions, even when installed at a corner.

The present invention may provide a light emitting apparatus capable of achieving uniform and vivid color and luminance across an entire display region.

### Technical Solution

A light emitting apparatus according to an embodiment of the present invention is a light emitting apparatus installed on a side wall of a structure having an angled corner, in which an illuminance measured along a reference line that is perpendicular to a bisecting line that evenly divides a corner angle formed at the corner and is spaced apart by a predetermined distance in an extension direction of the bisecting line may have a maximum value at a central position corresponding to the bisecting line.

In an embodiment, the light emitting apparatus may include a plurality of light emitting modules arranged such that their respective side surfaces abut each other at the corner.

In an embodiment, the light emitting module may include a substrate, a plurality of light emitting devices disposed on a surface of the substrate, and a molding part covering the plurality of light emitting devices.

In an embodiment, a viewing angle of each of the plurality of light emitting devices may be 80° or less.

In an embodiment, the light emitting module may further include a coating layer disposed on a side of the molding part. The light emitting module may further include a light control layer disposed over the plurality of light emitting devices.

In an embodiment, the light control layer may be a lens array disposed over the plurality of light emitting devices.

In an embodiment, the light control layer may be a reflector disposed over the plurality of light emitting devices.

In an embodiment, the light control layer may be a light-blocking layer configured to block light from at least a portion of a light exiting surface.

In an embodiment, the light emitting module may have an inclined surface that coincides with the bisecting line on at least one surface.

In an embodiment, a side surface of an adjacent light emitting module in a region of the structure other than the corner may be a vertical surface perpendicular to a light exiting surface.

In an embodiment, an interval between two adjacent light emitting devices at the corner may be smaller than an interval between two adjacent light emitting devices in other regions.

In an embodiment, the structure may be an exterior wall of a building, an interior wall of a building, or a side wall of a column.

A light emitting apparatus according to an embodiment of the present invention is a light emitting apparatus installed on a side wall of a structure having an angled corner, and when measuring an illuminance along a reference line that is perpendicular to a bisecting line that evenly divides a corner angle formed at the corner and is spaced apart by a predetermined distance in an extension direction of the bisecting line, an illuminance at a position spaced 5 mm apart from a central position corresponding to the bisecting line may be 85% or more of a maximum illuminance value.

In an embodiment, the illuminance may have the maximum value at the central position corresponding to the bisecting line.

A light emitting apparatus according to an embodiment of the present invention is a light emitting apparatus installed on a side wall of a structure having an angled corner, and may include a plurality of light emitting modules arranged such that their respective side surfaces abut each other at the corner.

In an embodiment, the light emitting module may have an inclined surface that coincides with the bisecting line on at least one side surface.

In an embodiment, the light emitting module may include a substrate, a plurality of light emitting devices disposed on a surface of the substrate, and a molding part covering the plurality of light emitting devices.

In an embodiment, a cross-sectional width of the light emitting module may decrease in a direction from the substrate toward a light exiting surface.

In an embodiment, the cross-sectional width of the light emitting module may increase in the direction from the substrate toward the light exiting surface.

In an embodiment, an interval between two adjacent light emitting devices at the corner may be smaller than an interval between two adjacent light emitting devices in other regions.

### Advantageous Effect

The present invention may provide a light emitting apparatus capable of achieving uniform and bright luminance without any dark regions, even when installed at a corner.

The present invention may provide a light emitting apparatus capable of achieving uniform and vivid color and luminance across an entire display region.

### BRIEF DESCRIPTION OF THE DRAWINGS

FIG. 1A is a view illustrating a portion of a light emitting apparatus according to an embodiment of the present invention.

FIG. 1B is a view illustrating a portion of a light emitting apparatus according to another embodiment of the present invention.

FIG. 2A is an enlarged view of a magnified portion of the light emitting apparatus of FIG. 1A.

FIG. 2B is an enlarged view of a magnified portion of the light emitting apparatus of FIG. 1B.

FIG. 3 is a view illustrating a light emitting module of the light emitting apparatus of FIG. 2A.

FIG. 4 is a schematic diagram illustrating a method of measuring illuminance at a corner of the light emitting apparatus of FIG. 2A is illustrated.

FIGS. 5A through 5D are diagrams illustrating brightness as a function of viewing angle for the light emitting apparatus of FIG. 2A.

FIGS. 6A through 6D are graphs illustrating illuminance as a function of position for different viewing angles of the light emitting device disposed in the light emitting apparatus of FIG. 2A.

FIG. 6E is a graph illustrating illuminance distribution along first and second directions when a side surface of a light-emitting module is not an inclined surface.

FIG. 7 is a graph comparing the normalized illuminance distribution shown in FIGS. 6A through 6D.

FIG. 8 is a diagram illustrating a plurality of light emitting devices arranged in an N×M matrix in a light emitting module.

### DETAILED DESCRIPTION OF THE ILLUSTRATED EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus of the present invention will be described in detail through the accompanying drawings.

The light emitting apparatus may be a display apparatus for installation on a structure having an angled corner, such as an exterior wall, interior wall of a building 1, or side wall of a column 2. The light emitting apparatus may include a plurality of light emitting modules 100 installed adjacent to each other. The light emitting modules 100, with their side surfaces abutting each other, may form a single display.

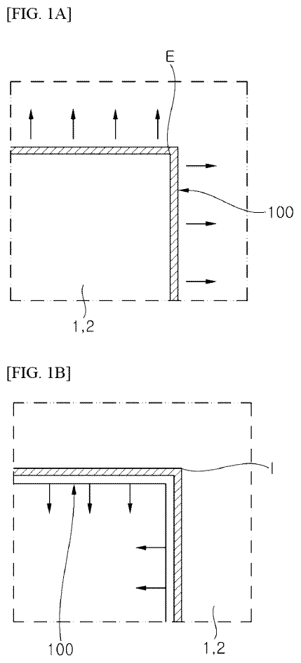

Meanwhile, referring to FIGS. 1A and 1B, corners E and I where adjacent wall surfaces meet at an angle may be formed on the exterior wall, interior wall of the building 1, or an exterior surface of the column 2, or others. At the corners E and I, the side surfaces of the light emitting modules 100 may abut each other to form a single display.

FIG. 1A illustrates an example where the light emitting apparatus is installed at a protruding side wall corner E of the building 1 or at a protruding corner E of the column 2. FIG. 1B illustrates an example where the light emitting apparatus is installed at a recessed side wall corner I of the building 1 or at a recessed corner I of the column 2.

Accordingly, the light emitting apparatus may include a plurality of light emitting modules 100 arranged such that their respective side surfaces abut each other at the corner.

The light emitting module 100 may include a substrate 110, a plurality of light emitting devices 120 disposed on a surface of the substrate 110, and a molding part 130 covering the plurality of light emitting devices 120.

In addition, the light emitting module 100 may further include a coating layer 140 disposed on a side of the molding part 130.

The substrate 110 is a substrate on which the light emitting devices 120 are disposed on a surface, and may include a circuit board, a support frame, or others. The substrate 110 may be electrically connected to the light emitting devices 120 to supply power thereto for the light emitting devices 120. The substrate 110 may be equipped with various IC circuits for driving the light emitting devices 120.

The substrate 110 may be formed as a single layer or a multilayer structure, and may be formed with various thicknesses as needed.

The plurality of light emitting devices 120 may be arranged in various patterns on an upper surface of the substrate 110. For example, three light emitting devices 120 that emit red, green, and blue light, respectively, may be disposed at a regular interval to form a group or pixel. The plurality of light emitting devices 120 may reproduce light of a wide color range using red, green, and blue light. Alternatively, a group or pixel may be formed by vertically stacking red, green, and blue light emitting diodes on a single light emitting device 120. In addition, the light emitting devices 120 may be formed of diode devices that emit light of a same color range. For example, a difference in dominant wavelength between adjacent light emitting devices 120 may be in a range of 2 nm to 15 nm, thereby achieving a more vivid color.

Alternatively, the plurality of light emitting devices 120 may be grouped to form a plurality of groups or pixels. The plurality of groups or pixels may be arranged in a grid shape on the substrate 110. An interval between adjacent light emitting devices 120 may be set in various ways.

For example, the light emitting device 120 is a light emitting diode device that is disposed on a surface of the substrate 110 to emit light, and various configurations are possible. The light emitting device 120 may include a semiconductor layer formed on a growth substrate. The growth substrate may be removed after the semiconductor layer is grown.

In detail, the light emitting device 120 may include a first conductivity type semiconductor layer, a second conductivity type semiconductor layer, and an active layer disposed between the first conductivity type semiconductor layer and the second conductivity type semiconductor layer.

The first conductivity type semiconductor layer may be a semiconductor layer grown on a surface of the growth substrate, and may include a phosphide or nitride semiconductor such as (Al, Ga, In)P or (Al, Ga, In)N. The first conductivity type semiconductor layer may be doped as an n-type by including one or more impurities such as Si, C, Ge, Sn, Te, Pb, or others. However, the inventive concepts are not limited thereto, and the first conductivity type semiconductor layer may be doped with an opposite conductivity type including a p-type dopant.

The active layer is a light emitting layer disposed on a side of the first conductivity type semiconductor layer, and may include a phosphide or nitride semiconductor such as (Al, Ga, In)P or (Al, Ga, In)N.

In addition, the active layer may include a quantum well structure (QW) including at least two barrier layers and at least one well layer, and furthermore, may include a multi quantum well structure (MQW) including a plurality of barrier layers and a plurality of well layers. A wavelength of light emitted from the active layer may be adjusted by controlling a composition ratio of a material forming the well layer. In this case, the well layer may commonly include a same element, and may include, for example, In.

The second conductivity type semiconductor layer may be a semiconductor layer disposed on a side of the active layer. The second conductivity type semiconductor layer may include a phosphide or nitride semiconductor such as (Al, Ga, In)P or (Al, Ga, In)N, and may be doped with a conductivity type opposite to that of the first conductivity type semiconductor layer. For example, the second conductivity type semiconductor layer may be doped with a p-type by including an impurity such as Mg.

The light emitting device 120 may have a light exiting surface formed on the side of the first conductivity type semiconductor layer or the second conductivity type semiconductor layer through which light is emitted.

As another example, the light emitting device 120 may be a stacked semiconductor layer in which a plurality of light emitting diodes are stacked and disposed. The stacked semiconductor layer may include a first light emitting stack, a second light emitting stack and a third light emitting stack that are sequentially stacked. The second light emitting stack may be disposed over the first light emitting stack, and the third light emitting stack may be sequentially stacked over the second light emitting stack. Each of the first through third light emitting stacks may include a first conductivity type semiconductor layer, an active layer, and a second conductivity type semiconductor layer.

The first through third light emitting stacks may be a light emitting stack emitting red light, a light emitting stack emitting green light, and a light emitting stack emitting blue light, respectively. Therefore, a stacked light emitting device 120 including the first through third light emitting stacks may display RGB primary colors as pixels.

It will be understood that the light emitting device 120 may be implemented in various modified structures, such as flip-chip type, vertical type, lateral type, or others.

The molding part 130 is a layer covering the light emitting device 120 and the substrate 110, and may be light-transmissive. Light emitted from the light emitting device 120 may pass through the molding part 130 and be emitted to the outside. In this case, the molding part 130 may include particles to improve optical characteristics. The particles may be light-reflective or light-absorbing materials. The particles may change a light path or change optical characteristics such as decreasing or increasing an amount of light emitted to the outside.

The coating layer 140 is a layer disposed on a side of the molding part 130, and may form a light exiting surface. In addition, the coating layer 140 may be a film having a refractive index and a reflectance different from that of the molding part 130, and may be attached to a surface of the molding part 130 through an adhesive material. The coating layer 140 may also perform a function of a protection layer that protects the light emitting module 100 from the outside. The coating layer 140 may include an optical pattern for forming a viewing angle which will be described later. A portion of the optical pattern may have an arrangement parallel to a bisecting line M which will be described later. This may improve the light uniformity of the light emitting apparatus may be improved by reducing an occurrence of dark lines or bright lines near the bisecting line M.

Meanwhile, the light emitting module 100 may further include a light control layer disposed over the plurality of light emitting devices 120. The light control layer may be configured in various ways as long as it is capable of controlling the light path of light emitted from the light emitting device 120.

For example, the light control layer may be a lens array disposed over the plurality of light emitting devices 120. As another example, the light control layer may be a reflector disposed over the plurality of light emitting devices 120. As another example, the light control layer may be a light-blocking layer that block light from at least a portion of a light exiting surface.

The light control layer may be disposed between the light emitting device 120 and the molding part 130, or between the molding part 130 and the coating layer 140.

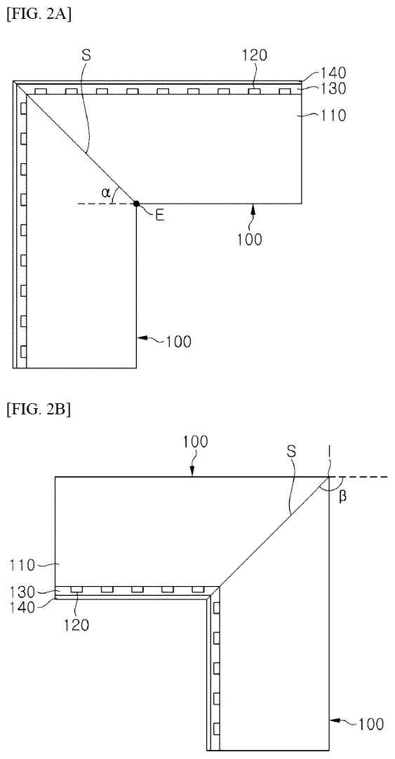

Next, referring to FIGS. 2A and 2B, the light emitting apparatus may include the plurality of light emitting modules 100 in which one side surface thereof abuts against one side surface thereof at the protruding corner and the recessed corner E and I.

In this case, a bisecting line that evenly divides a corner angle formed at the corners E and I may be defined. The light emitting module 100 may have an inclined surface S that coincides with the bisecting line on at least one side surface. For example, the corner angle formed at the corners E and I may be 90°, and at least one side surface of the light emitting module 100 may be an inclined surface S having an inclination angle α or β that coincides with the bisecting line.

In a case of FIG. 2A, the inclined side surface S of the light emitting module 100 installed at the protruding corner E is illustrated, and in a case of FIG. 2B, the inclined side surface S of the light emitting module 100 installed at the recessed corner I is illustrated. Therefore, the inclination angle a formed by the side surface of the light emitting module 100 at the protruding corner E with respect to an extension line of a bottom surface of the substrate 110 may be an acute angle, and the inclination angle β formed by the side surface of the light emitting module 100 at the recessed corner I with respect to the extension line of the bottom surface of the substrate 110 may be an obtuse angle.

The inclined surface S may have roughness such that light can be well mixed at the corners E and I. In this case, the inclined surface S having the roughness may be formed on at least one of the coating layer 140 and the molding part 130. In addition, to reduce an occurrence of bright lines on corner E and I regions, a light absorbing layer with a transmittance different from that of the molding part 130 may be further disposed on a partial region of the inclined surface S. The light absorbing layer may include carbon, pigment, metal coating, or others.

In the case of FIG. 2A, as the inclination angle α formed by the side surface of the light emitting module 100 with respect to the extension line of the bottom surface of the substrate 110 appears as an acute angle, a cross-sectional width of the light emitting module 100 may increase in a direction toward the light exiting surface from the substrate 110.

On the contrary, in the case of FIG. 2B, as the inclination angle β formed by the side surface of the light emitting module 100 with respect to the extension line of the bottom surface of the substrate 110 appears as an obtuse angle, the cross-sectional width of the light emitting module 100 may decrease in the direction toward the light exiting surface from the substrate 110.

In a case where the light emitting module 100 has a rectangular shape in plan view, the light emitting module 100 may have a total of four side surfaces, and in this case, it is not necessary for all side surfaces to be formed of inclined surfaces S. A side surface of the light emitting module 100 that meets an adjacent light emitting module 100 in a non-corner region E and I does not need to be the inclined surface S, and it is sufficient that this side surface is a vertical surface.

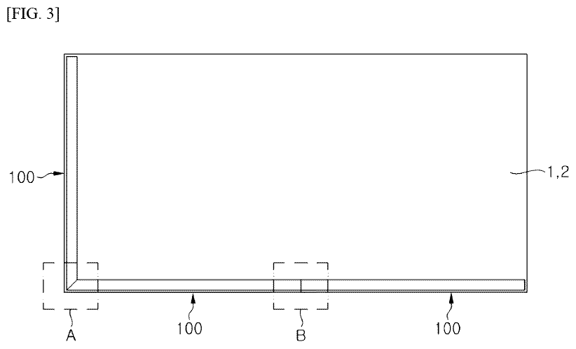

That is, as illustrated in FIG. 3, a side surface of an adjacent light emitting module 100 in other regions B of the structure 1 or 2, excluding a region A having the corner E or I, may be a vertical surface perpendicular to the light exiting surface. Consequently, inclination degrees of the side surfaces of the light emitting module 100 may be different depending on positions thereof.

Referring again to FIG. 2A and FIG. 2B, as described above, in a case where the inclined surface S is formed on the side surface of the light emitting module 100, when adjacent light emitting modules 100 meet at the corners E and I, they may be in close contact without any separation space between side surfaces thereof, and it is possible to effectively prevent a dark region from appearing at the corners E and I. To this end, the inclined surface S may be formed over entire side surfaces of the light emitting module 100.

In addition to the side surface of the light emitting module 100 having the inclined surface S, an interval between two adjacent light emitting devices 120 at the corners E and I may be smaller than an interval between two adjacent light emitting devices 120 in the other regions. By making the interval between the light emitting devices 120 smaller at the corners E and I, it is possible to effectively prevent a decrease in brightness of the light emitting apparatus at the corners E and I.

In particular, the light emitting module 100 according to the present invention may implement uniform luminance and color of an entire light emitting apparatus by ensuring that an illuminance measured at the corners E and I has a value greater than that of the other regions.

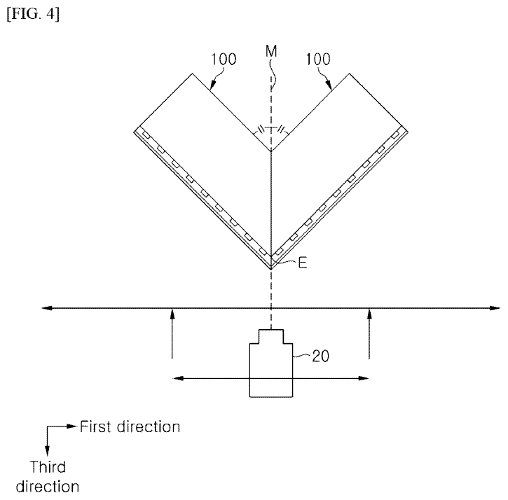

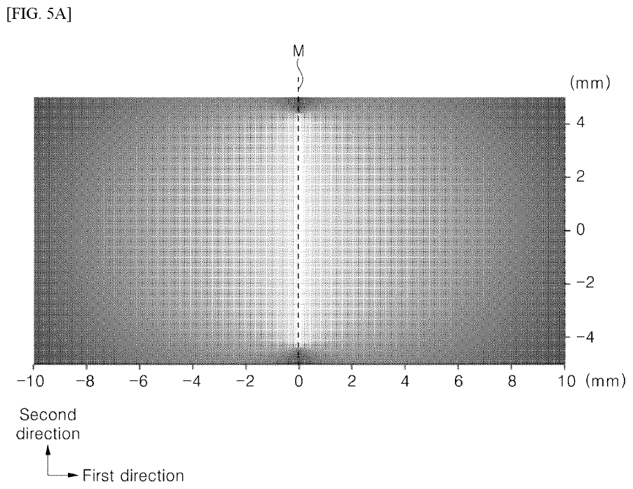

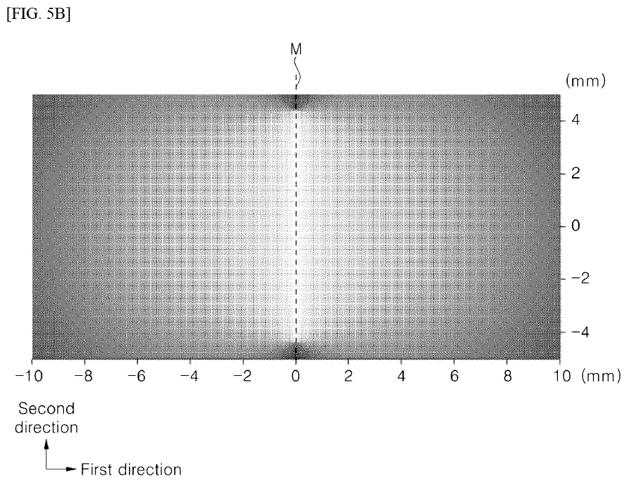

In detail, the illuminance at the corner E of the light emitting apparatus may be measured in a manner illustrated in FIG. 4. As illustrated in FIG. 4, an illuminance measuring apparatus 20 may measure an illuminance of the light emitting apparatus by moving along an extension line spaced apart from the corner E by a predetermined distance, perpendicular to a bisecting line M that evenly divides the corner angle formed at the corner E of the structure. In FIG. 4, a two-way arrow indicates a path along which the illuminance measuring apparatus 20 moves along the reference line. The predetermined separation distance at the corner E may be 10 cm or more and less than 1 m. FIG. 4 illustrates the light emitting apparatus installed in the protruding corner E, but the above-described illuminance measurement manner may be applied in a same way to a light emitting apparatus installed in the recessed corner I.

The illuminance measured by the illuminance measuring apparatus 20 moving along a reference line may have a maximum value at a central position corresponding to the bisecting line M.

In addition, an illuminance measured at a position spaced 5 mm away from the central position corresponding to the bisecting line M may be 85% or more of the maximum illuminance value. In this case, the maximum illuminance value may appear at the central position corresponding to the bisecting line M.

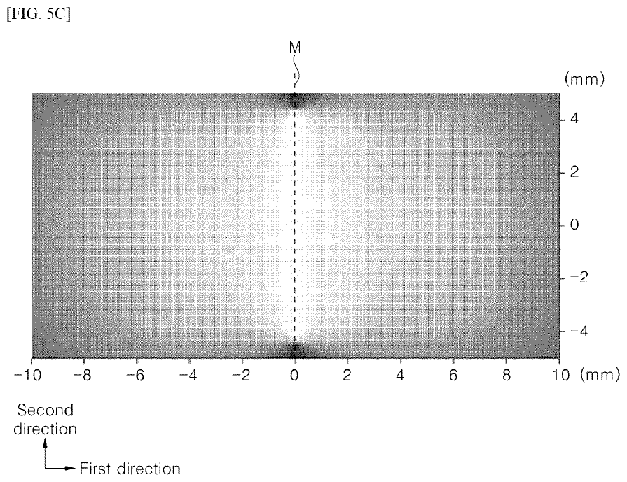

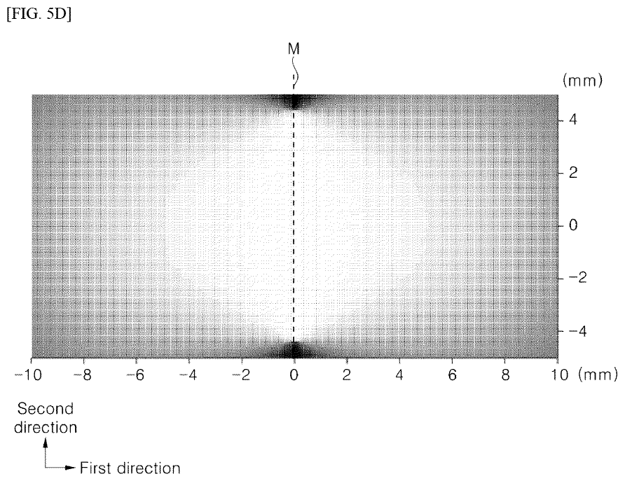

FIG. 5A shows a brightness according to a first direction and a second direction when the illuminance is measured in the corner E region as in FIG. 4, and a viewing angle of the light emitting device 120 is set to 120°. Herein, the first direction may be a direction parallel to the reference line in which the illuminance measuring apparatus 20 moves, and the second direction may be perpendicular to the first direction and parallel to an extension direction of the corner E.

Referring to FIG. 5A, a point 0 mm based on the first direction may be the central position corresponding to the bisecting line M, and it can be seen that a corresponding position thereof has a greatest brightness.

FIG. 5B is a result obtained by changing the viewing angle of the light emitting device 120 into 100°, FIG. 5C is a result obtained by changing the viewing angle of the light emitting device 120 into 80°, and FIG. 5D is a result obtained by changing the viewing angle of the light emitting device 120 into 60°.

Although the distribution of illuminance at the corners (E, I) varies depending on the viewing angle of the light-emitting device (120), the maximum value of illuminance consistently appears at the 0 mm point in the first direction, i.e., the central position corresponding to the bisecting line (M).

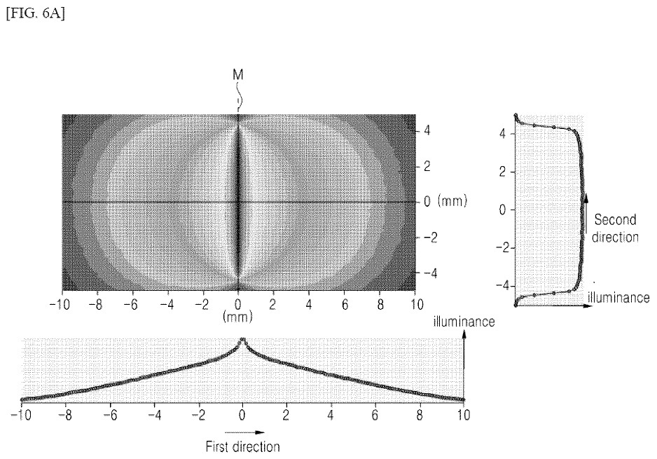

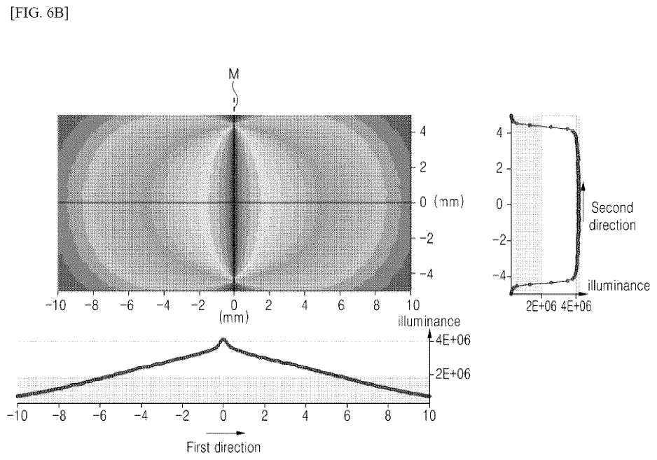

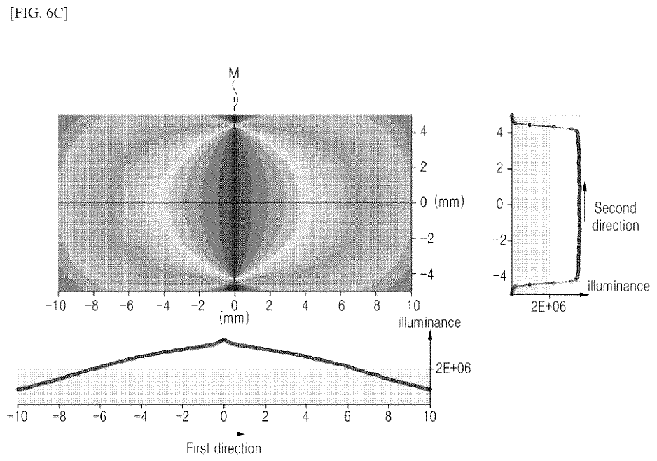

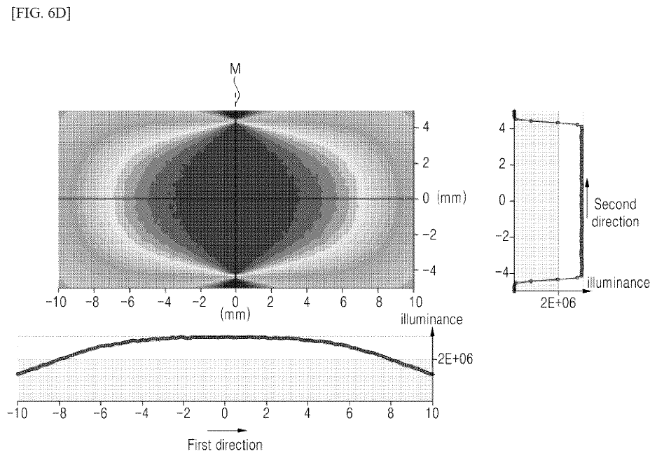

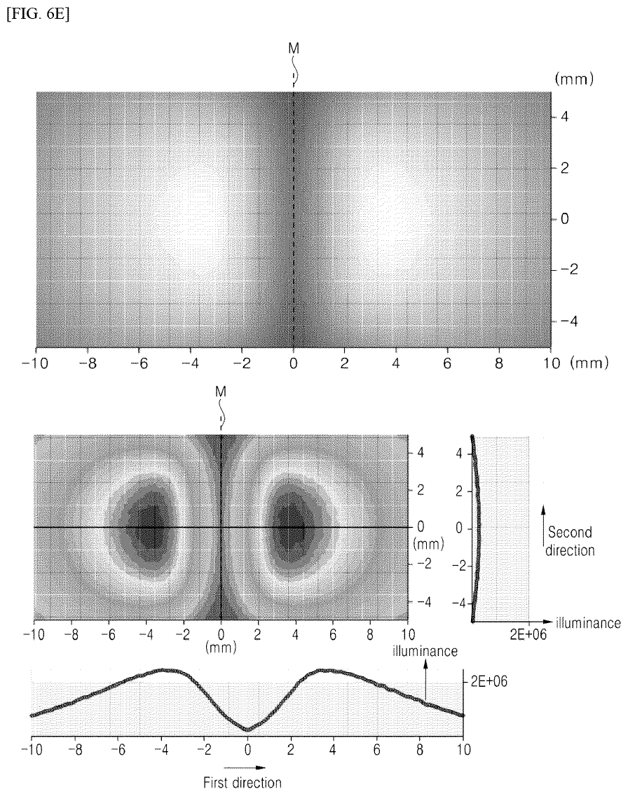

FIGS. 6A through 6D are diagrams that show visualization and graphization of the illuminance by position in the first direction and the second direction, respectively, with respect to FIGS. 5A through 5D.

It can be confirmed that all of FIGS. 6A through 6D have the greatest illuminance value at the central position corresponding to the bisecting line M, that is, the point 0 mm based on the first direction.

However, it can be seen that a deviation of the first direction illuminance varies depending on the viewing angle of the light emitting device 120. FIG. 6A shows a case where the viewing angle of the light emitting device 120 is 120°, and a deviation in illuminance between the central position and an outer position in the first direction appears large, but from FIG. 6B toward FIG. 6D, that is, as the viewing angle of the light emitting device 120 decreases, it can be seen that a deviation in illuminance between the central position and the outer position in the first direction decreases.

For example, referring to FIG. 6A, it has the greatest illuminance value at the central position corresponding to the bisecting line M, which is the 0 mm point based on the first direction, and the illuminance value may gradually decrease as the first direction position value increases or decreases. In particular, the change in illuminance may be greatest within a range of −1 mm or 1 mm centered at 0 mm in the first direction. As described above, by causing the illuminance to gradually decrease from the central position, a display apparatus that provides a three-dimensional appearance in the corner (E) region may be implemented.

As another example, referring to FIG. 6B, a light emitting apparatus may be implemented in which the illuminance changes gradually as it is away from the central position corresponding to the bisecting line M, that is, the point 0 mm based on the first direction. In particular, an illuminance at −4 mm to 4 mm from 0 mm based on the first direction may be maintained at a value of 50% or more relative to a peak illuminance.

As another example, referring to FIG. 6C, the change in illuminance in entire regions (−10 mm to 10 mm) based on the first direction may have a gentle shape. When moving by 1 mm based on the first direction, a slope of the illuminance (change in illuminance) at each distance may gradually become gentler. Through this, it is possible to easily implement a light emitting apparatus with low illuminance deviation on a flat surface while implementing a three-dimensional display at the corner E.

As another example, referring to FIG. 6D, it has a gentle illuminance distribution in which there may be little change in illuminance in the first direction at −4 mm to +4 mm based on the first direction. In this case, the illuminance at the corner E region corresponding to the bisecting line M may have little difference from an illuminance in a periphery, for example, at a position moving +4 mm away from the central position of the first direction. In this case, the difference in illuminance may be less than 10% of the peak illuminance. Through this, it is possible to implement a display apparatus that emits light that looks like planar light when observed in the corner E region.

It is preferable that the viewing angle of the light emitting device 120 be designed to be 80° or less, more preferably 60° or less. In this case, it is also possible to fix the viewing angle of the light emitting device 120 and control a light path of emitted light through the light control layer described above to reduce the illuminance deviation.

FIG. 6E shows the illuminance distribution along the first and second directions when the side surface of the light-emitting module (100) is not an inclined surface(S). In this case, the illuminance at the corners (E, I) may be reduced. In other words, the illuminance value at the central position corresponding to the bisecting line (M), that is, the 0 mm point in the first direction, is lower than that of the periphery.

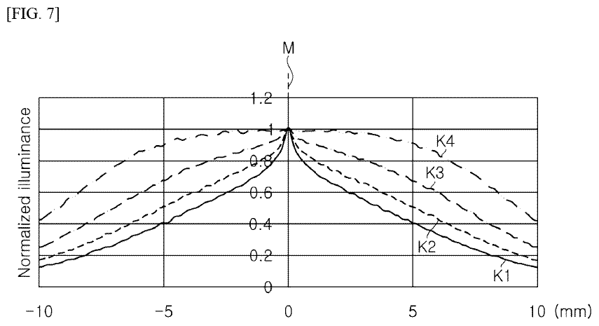

FIG. 7 is a graph comparing the normalized illuminance distributions along the first direction from FIGS. 6A to 6D. In FIG. 7, Kl represents the normalized illuminance distribution from FIG. 6A, K2 represents the normalized illuminance distribution from FIG. 6B, K3 represents the normalized illuminance distribution from FIG. 6C, and K4 represents the normalized illuminance distribution from FIG. 6D. A comparison of K1 to K4 shows that K4 exhibits the smallest illuminance deviation along the first direction and the most uniform luminance across the regions.

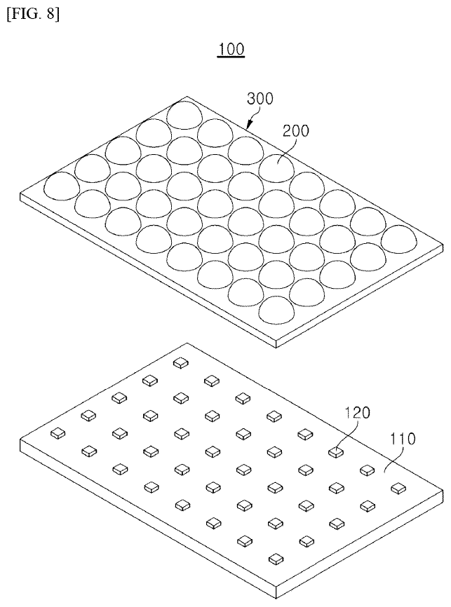

Meanwhile, referring to FIG. 8, a plurality of light emitting devices 120 may be arranged in an N×M matrix (N and M are positive integers) in a light emitting module 100. The plurality of light emitting devices 120 may be spaced apart from one other along an upper surface of a substrate 110. The plurality of light emitting devices 120 may have viewing angles different from one another. The light emitting module 100 may include first, second, and third light emitting devices 120 having viewing angles different from one another.

In this case, the light emitting module 100 may further include a lens 300 disposed on an upper surface thereof. The lens 300 may be disposed on light exiting surfaces of the light emitting devices 120 to adjust the viewing angle.

The lens 300 may include a refractive portion 200 which is a curved region and a flat region. A plurality of refractive portions 200 may be provided. Each refractive portion 200 may have a convex shape.

In this case, the refractive portions 200 may be disposed in an arrangement corresponding to the N×M matrix of light emitting devices 120. The refractive portion 200 may adjust the viewing angle of light emitted from a corresponding light emitting device 120 through the convex shape. The refractive portions 200 may be spaced apart from one another along the plurality of light emitting devices 120 spaced apart on the substrate 110. In this case, a spacing between the light emitting devices 120 may be greater than a spacing between the refractive portions 200, and accordingly, it is possible to reduce light interference between the light emitting devices 120 that are spaced apart.

A lower width of the refractive portion (200) may be larger than a width of the light-emitting device (120). A viewing angle range of light refracted by the refractive portion (200) may be narrower than the viewing angle range of the light-emitting device (120). In addition, a height of the refractive portion 200 may be higher than that of the light emitting device 120. For example, a thickness of the refractive portion (200) may be 1.1 times or more than the thickness of the light-emitting device (120).

The planar region may be disposed between light emitting regions of the light emitting device 120, thereby reducing light interference between each light emitting device 120.

In addition, to protect the light emitting devices 120 from an external environment, a height of the lens 300 may be higher than that of the light emitting devices 120. However, if the height of the lens (300) is unnecessarily high, light loss may occur, and thus an appropriate height is required. For example, the thickness of the lens (300) may be in a range of 1.1 to 3 times the thickness of the light-emitting device (120).

Although the present invention has been described above with reference to preferred embodiments, those skilled in the art or those with ordinary knowledge in the art will understand that various modifications and changes can be made to the invention without departing from the spirit and technical scope of the invention as described in the claims set forth below.

Therefore, the technical scope of the present invention should not be limited to the contents described in the detailed description of the specification, but should be determined by the claims.

### DESCRIPTION OF REFERENCE NUMERALS

20: Illuminance measuring device
100: Light emitting module
110: Substrate
120: Light emitting device
130: Molding part
140: Coating layer

1. A light emitting apparatus installed on a side wall of a structure having an angled corner,
wherein an illuminance measured along a reference line that is perpendicular to a bisecting line that evenly divides a corner angle formed at the corner and is spaced apart by a predetermined distance in an extension direction of the bisecting line has a maximum value at a central position corresponding to the bisecting line.

2. The light emitting apparatus of claim 1, comprising:
a plurality of light emitting modules arranged such that their respective side surfaces abut each other at the corner.

3. The light emitting apparatus of claim 2,
wherein the light emitting module includes a substrate, a plurality of light emitting devices disposed on a surface of the substrate, and a molding part covering the plurality of light emitting devices.

4. The light emitting apparatus of claim 3,
wherein a viewing angle of each of the plurality of light emitting devices is 80° or less.

5. The light emitting apparatus of claim 3,
wherein the light emitting module further comprises a coating layer disposed on a side of the molding part.

6. The light emitting apparatus of claim 3,
wherein the light emitting module further comprises a light control layer disposed over the plurality of light emitting devices.

7. The light emitting apparatus of claim 6,
wherein the light control layer is a lens array disposed over the plurality of light emitting devices.

8. The light emitting apparatus of claim 6,
wherein the light control layer is a reflector disposed over the plurality of light emitting devices.

9. The light emitting apparatus of claim 6,
wherein the light control layer is a light-blocking layer configured to block light from at least a portion of a light exiting surface.

10. The light emitting apparatus of claim 3,
wherein the light emitting module has an inclined surface that coincides with the bisecting line on at least one side surface.

11. The light emitting apparatus of claim 10,
wherein a side surface of an adjacent light emitting module in a region of the structure other than the corner is a vertical surface perpendicular to a light exiting surface.

12. The light emitting apparatus of claim 1,
wherein an interval between two adjacent light emitting devices at the corner is smaller than an interval between two adjacent light emitting devices in other regions.

13. The light emitting apparatus of claim 1,
wherein the structure is an exterior wall of a building, an interior wall of a building, or a side wall of a column.

14. A light emitting apparatus installed on a side wall of a structure having an angled corner,
wherein, when measuring an illuminance along a reference line that is perpendicular to a bisecting line that evenly divides a corner angle formed at the corner and is spaced apart by a predetermined distance in an extension direction of the bisecting line, an illuminance at a position spaced 5 mm apart from a central position corresponding to the bisecting line is 85% or more of a maximum illuminance value.

15. The light emitting apparatus of claim 14,
wherein the illuminance has the maximum value at the central position corresponding to the bisecting line.

16. A light emitting apparatus installed on a side wall of a structure having an angled corner, comprising:
a plurality of light emitting modules arranged such that their respective side surfaces abut each other at the corner,
wherein the light emitting module has an inclined surface that coincides with a bisecting line on at least one side surface.

17. The light emitting apparatus of claim 16,
wherein the light emitting module includes a substrate, a plurality of light emitting devices disposed on a surface of the substrate, and a molding part covering the plurality of light emitting devices.

18. The light emitting apparatus of claim 17,
wherein a cross-sectional width of the light emitting module decreases in a direction from the substrate toward a light exiting surface.

19. The light emitting apparatus of claim 17,
wherein the cross-sectional width of the light emitting module increases in the direction from the substrate toward the light exiting surface.

20. The light emitting apparatus of claim 16,
wherein an interval between two adjacent light emitting devices at the corner is smaller than an interval between two adjacent light emitting devices in other regions.
